(19) United States
(12) Patent Application Publication
(10) Pub. No.: US 2026/0291219 A1
(43) Pub. Date: Sep. 24, 2026

(54) STORAGE DEVICE, SEMICONDUCTOR DEVICE AND ELECTRONIC APPARATUS

(71) Applicant: Yangtze Memory Technologies Co., Ltd., Wuhan (CN)

(72) Inventor: Fangjiang ZHA, Wuhan (CN)

(21) Appl. No.: 19/309,021

(22) Filed: Aug. 25, 2025

(30) Foreign Application Priority Data
Mar. 20, 2025 (CN) 202510336417.3
Mar. 20, 2025 (CN) 202520500212.X

(51) Int. Cl. H02H 9/04; H02H 9/00; H05K 1/02

(52) U.S. Cl. CPC H02H 9/04; H02H 9/005; H05K 1/0218; H05K 2201/10159

(57) ABSTRACT

A storage device, a semiconductor device and an electronic apparatus are provided by examples of the present disclosure. In an example, the storage device includes: a substrate; and a memory controller, a memory device, a first protection circuit and a first node on the substrate. A power pin is provided on the substrate and a plurality of through holes are provided in the substrate. The memory controller is connected to the power pin through the first node. The memory device is connected to the memory controller. A first terminal of the first protection circuit is connected to the first node, and a second terminal of the first protection circuit is connected to at least one of the plurality of through holes, where the through holes connected to the first protection circuit are configured to be grounded.

### CROSS-REFERENCE TO RELATED APPLICATIONS

This application claims priority to Chinese Patent Application No. 202510336417.3, filed on March 20, 2025, and Chinese Patent Application No. 202520500212.X, filed on March 20, 2025, which are hereby incorporated by reference in their entirety.

### TECHNICAL FIELD

Examples of the present disclosure relate to the field of semiconductor technology, and relate to, but are not limited to, a storage device, a semiconductor device, and an electronic apparatus.

### BACKGROUND

A solid state disk (SSD), also known as a solid state drive, generally refers to a hard disk made of a solid state electronic memory chip array. The SSD is widely used in military, vehicle, industrial control, video monitoring, network monitoring, network terminals, electrical power, medical treatment, aviation, navigation equipment and many other fields, due to its advantages such as fast reading and writing speed, low power consumption, and small size.

The SSD is fabricated based on semiconductor technology and thus is sensitive to voltage fluctuation. For example, in an operation process of the SSD, the voltage may have a sudden rise due to an external or internal factor and exceeds the normal operation voltage of the SSD, which may result in a failure of the SSD.

### SUMMARY

According to a first aspect of examples of the present disclosure, there is provided a storage device, comprising: a substrate; and a memory controller, a memory device, a first protection circuit and a first node on the substrate, where a power pin is provided on the substrate, and a plurality of through holes are provided in the substrate; the memory controller is connected to the power pin through the first node, the memory device is connected to the memory controller, a first terminal of the first protection circuit is connected to the first node, and a second terminal of the first protection circuit is connected to at least one of the plurality of through holes, where the through holes connected to the first protection circuit are configured to be grounded.

In some examples, the substrate further comprises a grounding layer and an isolation layer, where a grounding terminal of the memory controller and a grounding terminal of the memory device are both connected to the grounding layer, and the isolation layer is located between the through holes and the grounding layer.

In some examples, the storage device further comprises a connector on the substrate, where a first terminal of the connector is connected to the through holes connected to the first protection circuit, and a second terminal of the connector is connected to the grounding layer.

In some examples, the connector comprises at least one of a 0Ω resistor, a capacitor, an inductor, and a magnetic bead.

In some examples, the storage device further comprises a second protection circuit and a second node on the substrate, the memory device is connected to the power pin through the second node, a first terminal of the second protection circuit is connected to the second node, and a second terminal of the second protection circuit is connected to at least one of the plurality of through holes, where the through holes connected to the second protection circuit are configured to be grounded.

In some examples, a second terminal of the first protection circuit is connected to one of the plurality of through holes that is closest to the first protection circuit; and a second terminal of the second protection circuit is connected to one of the plurality of through holes that is closest to the second protection circuit.

In some examples, the first protection circuit and the second protection circuit each comprise a transient voltage suppressor.

In some examples, the first protection circuit is configured to discharge a transient overvoltage received by the power pin, such that the voltage received by the memory controller is less than or equal to an operation voltage of the memory controller; and the second protection circuit is configured to discharge a transient overvoltage received by the power pin, such that a voltage received by the memory device is less than or equal to an operation voltage of the memory device.

In some examples, a ratio of a sum of areas of the plurality of through holes to an area of the substrate is less than 0.05.

In some examples, the storage device further comprises a power management circuit on the substrate, an input terminal of the power management circuit is connected to the power pin through the first node, and an output terminal of the power management circuit is connected to the memory controller.

In some examples, the plurality of through holes comprise screw holes arranged at four corners of the substrate, and screws disposed in the screw holes are configured to fix the substrate.

In some examples, the storage device comprises a solid-state disk.

In some examples, the memory device comprises a 3D NAND memory.

According to a second aspect of examples of the present disclosure, there is provided a semiconductor device, comprising: a substrate; and a chip, a protection circuit and a node on the substrate, where a power pin is provided on the substrate, and a plurality of through holes are provided in the substrate; the chip is connected to the power pin through the node, a first terminal of the protection circuit is connected to the node, and a second terminal of the protection circuit is connected to at least one of the plurality of through holes, where the through holes connected to the protection circuit are configured to be grounded.

In some examples, the substrate further comprises a grounding layer and an isolation layer, a grounding terminal of the chip is connected to the grounding layer, and the isolation layer is located between the through holes and the grounding layer.

In some examples, the semiconductor device further comprises a connector on the substrate, where a first terminal of the connector is connected to the through holes connected to the protection circuit, and a second terminal of the connector is connected to the grounding layer.

In some examples, the connector comprises at least one of a 0Ω resistor, a capacitor, an inductor, and a magnetic bead.

In some examples, the semiconductor device comprises a plurality of chips that are all connected to the power pin through the node.

In some examples, the semiconductor device comprises a plurality of chips and a plurality of protection circuits, a first chip of the plurality of chips is connected to the power pin through a first node, a second chip of the plurality of chips is connected to the power pin through a second node different from the first node, a first terminal of a first protection circuit of the plurality of protection circuits is connected to the first node, a first terminal of a second protection circuit of the plurality of protection circuits is connected to the second node, and a second terminal of the first protection circuit and a second terminal of the second protection circuit are connected to a same one or different ones of the through holes.

In some examples, the second terminal of the protection circuit is connected to one of the plurality of through holes that is closest to the protection circuit.

In some examples, the protection circuit comprises a transient voltage suppressor.

In some examples, the protection circuit is configured to discharge a transient overvoltage received by the power pin, such that a voltage received by the chip is less than or equal to an operation voltage of the chip.

In some examples, a ratio of a sum of areas of the plurality of through holes to an area of the substrate is less than 0.05.

In some examples, the semiconductor device further comprises a power management circuit on the substrate, an input terminal of the power management circuit is connected to the power pin through the node, and an output terminal of the power management circuit is connected to the chip.

In some examples, the chip comprises at least one of a memory device and a memory controller.

In some examples, the plurality of through holes comprise screw holes arranged at four corners of the substrate; and the semiconductor device further comprises a housing and a screw, the substrate is mounted in the housing, the screws extend through the screw holes, and the substrate is connected to the housing through the screws.

According to a third aspect of examples of the present disclosure, there is provided an electronic apparatus, comprising: the storage device according to any example in the first aspect of examples of the present disclosure or the semiconductor device according to any example in the second aspect of examples of the present disclosure; and a host coupled to the storage device or the semiconductor device.

In the examples of the present disclosure, the first protection circuit is disposed on the substrate, the first terminal of the first protection circuit is connected to the memory controller and the first node on the power pin connection line, the second terminal of the first protection circuit is connected to at least one of the plurality of through holes provided on the substrate, and the through holes connected to the first protection circuit are configured to be grounded. As such, in a first aspect, the transient overvoltage may be discharged to the external ground line through the first protection circuit and the screw hole connected to the first protection circuit, so as to reduce impact of the transient overvoltage on the storage device and avoid a failure of the storage device; in a second aspect, the transient overvoltage is discharged through the screw hole, thereby avoiding the interference to the signal line on the substrate.

### BRIEF DESCRIPTION OF THE DRAWINGS

In the drawings, like reference numerals refer to the same or similar parts or elements throughout the various figures unless otherwise specified. The figures are not necessarily drawn to scale. It should be understood that these drawings depict only some implementations disclosed according to the present application and are not to be considered as limitations on the scope of the present application.

FIG. 1 is a schematic diagram of an example electronic apparatus having a storage device according to an example of the present disclosure.

FIG. 2A is a schematic diagram of an example memory card having a storage device according to an example of the present disclosure.

FIG. 2B is a schematic diagram of an example SSD having a storage device according to an example of the present disclosure.

FIG. 3A and FIG. 3B are schematic diagrams of a storage device according to an example of the present disclosure.

FIG. 4A is a schematic top view of a storage device having a first protection circuit according to an example of the present disclosure.

FIG. 4B is a schematic connection diagram of a storage device having a first protection circuit according to an example of the present disclosure.

FIG. 4C is a schematic connection diagram of a storage device having a second protection circuit according to an example of the present disclosure.

FIG. 5 is a schematic diagram of a transient voltage suppressor according to an example of the present disclosure.

FIG. 6A is a schematic diagram of a semiconductor device having a protection circuit according to an example of the present disclosure.

FIG. 6B is a schematic connection diagram of a semiconductor device having a protection circuit according to an example of the present disclosure.

FIG. 6C is a schematic connection diagram of a semiconductor device having a first protection circuit and a second protection circuit according to an example of the present disclosure.

### DETAILED DESCRIPTION

In order to facilitate understanding of the present disclosure, examples of the present disclosure will be described in more detail below with reference to the related drawings. Although the example implementations of the present disclosure are shown in the drawings, it should be understood that the present disclosure may be implemented in various forms and should not be limited by the specific examples set forth herein. On the contrary, these examples are provided to provide a more thorough understanding of the present disclosure and to fully convey the scope of the present disclosure to those skilled in the art.

In the following description, numerous specific details are set forth in order to provide a more thorough understanding of the present disclosure. However, it will be apparent to those skilled in the art that the present disclosure may be practiced without one or more of these details. In some examples, in order to avoid confusion with the present disclosure, some technical features known in the art are not described; that is, all features of an actual example may not be described herein, and well-known functions and structures are not described in detail.

In general, terminologies may be understood at least in part from usage in context. For example, the term “one or more” as used herein, depending at least in part upon the context, may be used to describe any feature, structure, or characteristic in a singular sense or may be used to describe combinations of features, structures or characteristics in a plural sense. Similarly, depending at least in part upon the context, terms such as “a,” “an,” or “the,” may be understood to convey a singular usage or to convey a plural usage. In addition, depending at least in part on context, a phrase “based on” may be understood as not necessarily intended to convey an exclusive set of factors and may instead allow for existence of additional factors not necessarily expressly described.

Unless otherwise defined, the terminologies used herein is for the purpose of describing particular examples only and is not intended to limit the disclosure. As used herein, the singular forms “a”, “an” and “the” are intended to include the plural forms as well, unless the context clearly indicates otherwise. It will be further understood that the terms “consist of” and/or “comprise”, when used in this specification, specify the presence of stated features, integers, steps, operations, elements, and/or components, but do not preclude the presence or addition of one or more other features, integers, steps, operations, elements, components, and/or groups thereof. As used herein, the term “and/or” comprises any and all combinations of the associated listed items.

In order to thoroughly understand the present disclosure, detailed steps and detailed structures are provided in the following description to explain the technical solutions of the present disclosure. Some examples of the present disclosure are described in detail below, but the present disclosure may have other implementations in addition to these detailed descriptions.

Before introducing the examples of the present disclosure, technical terms involved in this specification will be explained and illustrated. As used herein, “transient overvoltage” refers to a voltage in a power system that suddenly rises in a very short time (in the order of microseconds to milliseconds) to a value that exceeds the normal operation voltage of an electrical equipment. The generation of transient overvoltage is influenced by a variety of factors, such as lightning strikes, equipment switching operations, power failure, electrostatic discharge or parameter settings, etc.

Transient overvoltage on SSD power supply can easily damage the SSD. In an example such as an enterprise SSD product, the power supply of the enterprise SSD product supplies power from a server backplane and meanwhile supports hot plugging. When the server performs a transient interference (such as surge, static electricity, and Electrical Fast Transient (EFT)) immunity test, the residual voltage of the transient interference may be transferred to the SSD power supply, causing an SSD failure. In addition, a transient overvoltage generated during hot plugging of the SSD may also cause the SSD failure.

However, on the one hand, in order to suppress the transient overvoltage on the SSD power supply, there is high technical requirement on designs of the protection from transient overvoltage, the current discharge path of the transient overvoltage, and the grounding; on the other hand, these designs may lead to increased interference on the SSD signal lines.

Based on one or more of the above technical problems, examples of the present disclosure provide a storage device, a semiconductor device, and an electronic apparatus.

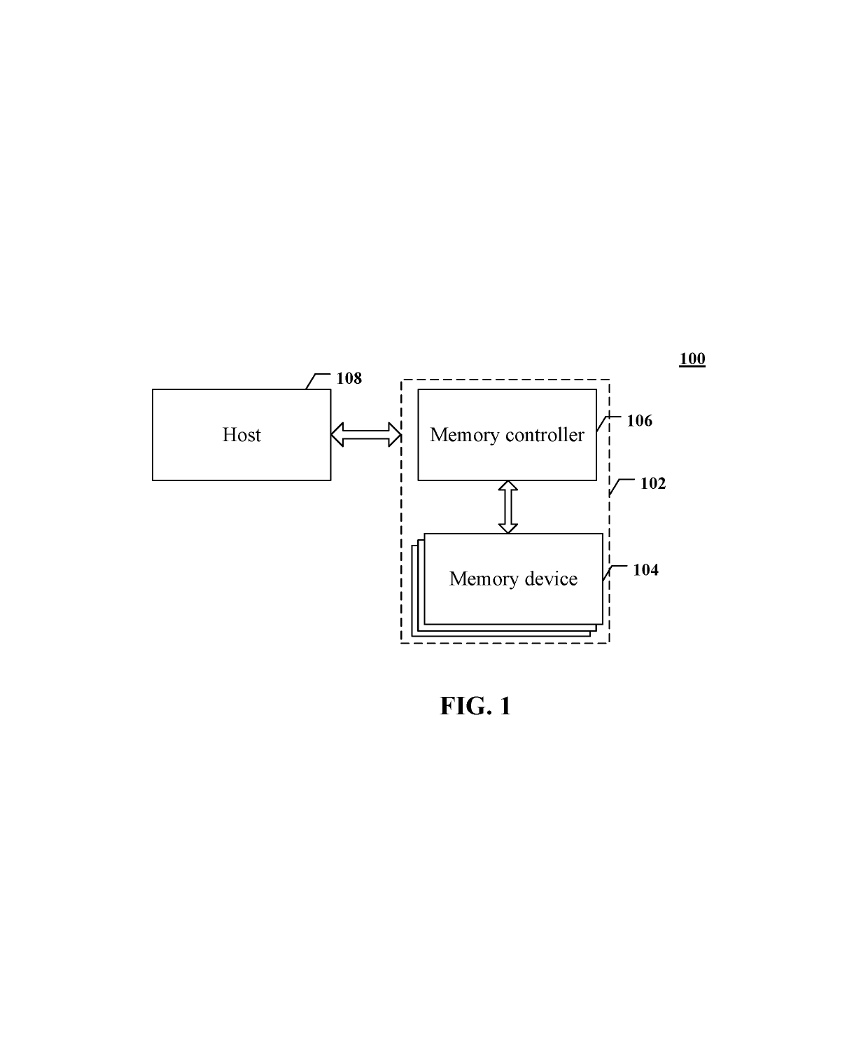

FIG. 1 is a schematic diagram of an example electronic apparatus having a storage device according to an example of the present disclosure. In the examples of the present disclosure, the electronic apparatus may be a mobile phone, a desktop computer, a laptop computer, a tablet computer, a vehicle computer, a game console, a printer, a positioning device, a wearable electronic apparatus, a smart sensor, a virtual reality (VR) device, an augmented reality (AR) device, or any other suitable electronic apparatus having a memory device therein.

Referring to FIG. 1, the electronic apparatus 100 may comprise a host 108 and a storage device 102, and the storage device 102 has one or more memory devices 104 and a memory controller 106. The host 108 may be a processor (e.g., a central processing unit (CPU)) or a system on chip (SoC) (e.g., an application processor (AP)) of the electronic apparatus. The host 108 can be configured to send data to the memory device 104 or receive data from the memory device 104.

In some examples, memory controller 106 is coupled to memory device 104 and host 108 and is configured to control memory device 104. Memory controller 106 can manage data stored in memory device 104 and communicate with host 108.

In some examples, the memory controller 106 is designed for operation in low duty cycle environments, such as secure digital (SD) cards, compact flash (CF) cards, universal serial bus (USB) flash drives, or other medium for use in electronic apparatus such as personal calculators, digital cameras, mobile phones, etc.

In other examples, the memory controller 106 is designed for operation in high duty cycle environments, such as SSDs or embedded Multi-Media Cards (eMMCs), and SSDs or eMMCs are used as data memory for mobile devices such as smartphones, tablet computers, laptop computers and the like, and enterprise memory arrays.

In some examples, memory controller 106 may be configured to control operations of memory device 104, such as read, erase, and program operations. The memory controller 106 may also be configured to manage various functions with respect to data stored or to be stored in the memory device 104 including, but not limited to, bad block management, garbage collection, logical-to-physical address translation, wear leveling, etc. The memory controller 106 is further configured to process an error correction code (ECC) on data read from the memory device 104 or written to the memory device 104.

Note that memory controller 106 may also perform any other suitable functions, such as formatting memory device 104. Memory controller 106 may communicate with an external device (e.g., host 108 in FIG. 1) according to a particular communication protocol. For example, the memory controller 106 may communicate with the external device through at least one of various interface protocols, such as USB protocol, MMC protocol, Peripheral Component Interconnect (PCI) protocol, Peripheral Component Interconnect Express (PCI-E) protocol, Advanced Technology Attachment (ATA) protocol, Serial ATA protocol, Parallel ATA protocol, Small Computer System Interface (SCSI) protocol, Enhanced Small Disk Interface (ESDI) protocol, Integrated Development Equipment (IDE) protocol, Firewire protocol, etc.

The memory controller 106 and the one or more memory devices 104 may be integrated into various types of memory apparatuses, for example, included in the same package (e.g., a Universal Flash Storage (UFS) package or an eMMC package). That is, the storage device 102 may be implemented and packaged into different types of end electronic products.

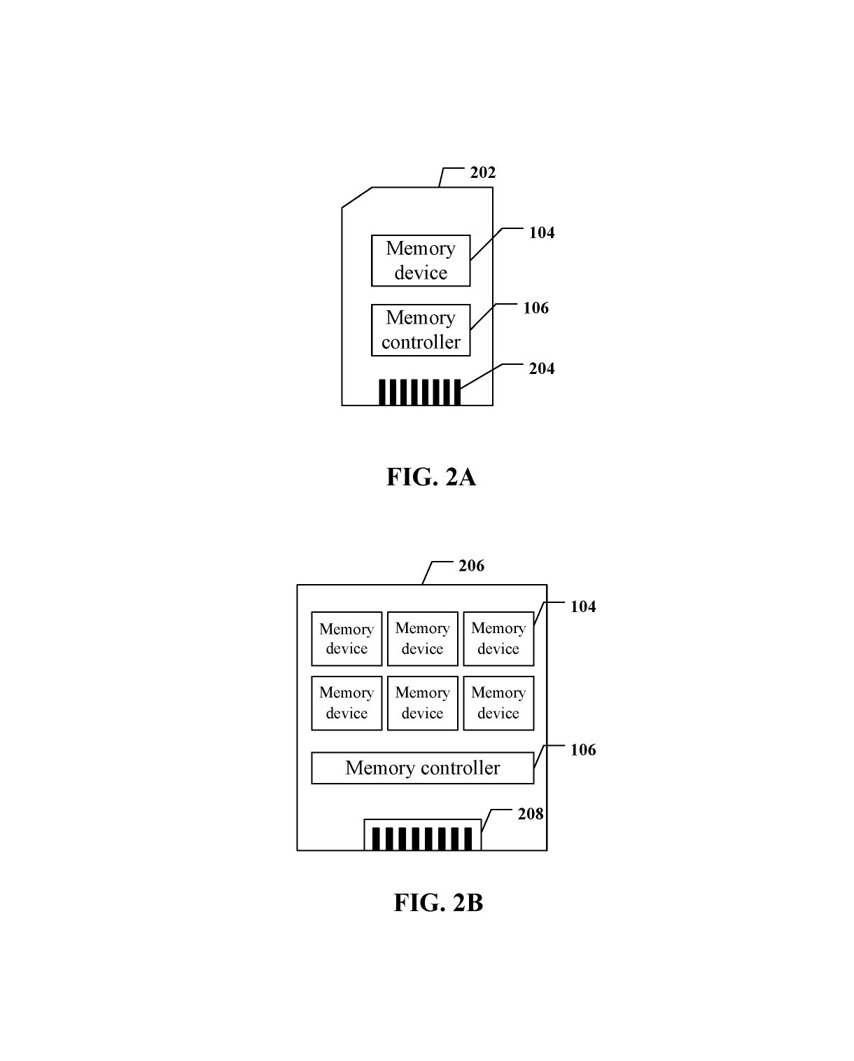

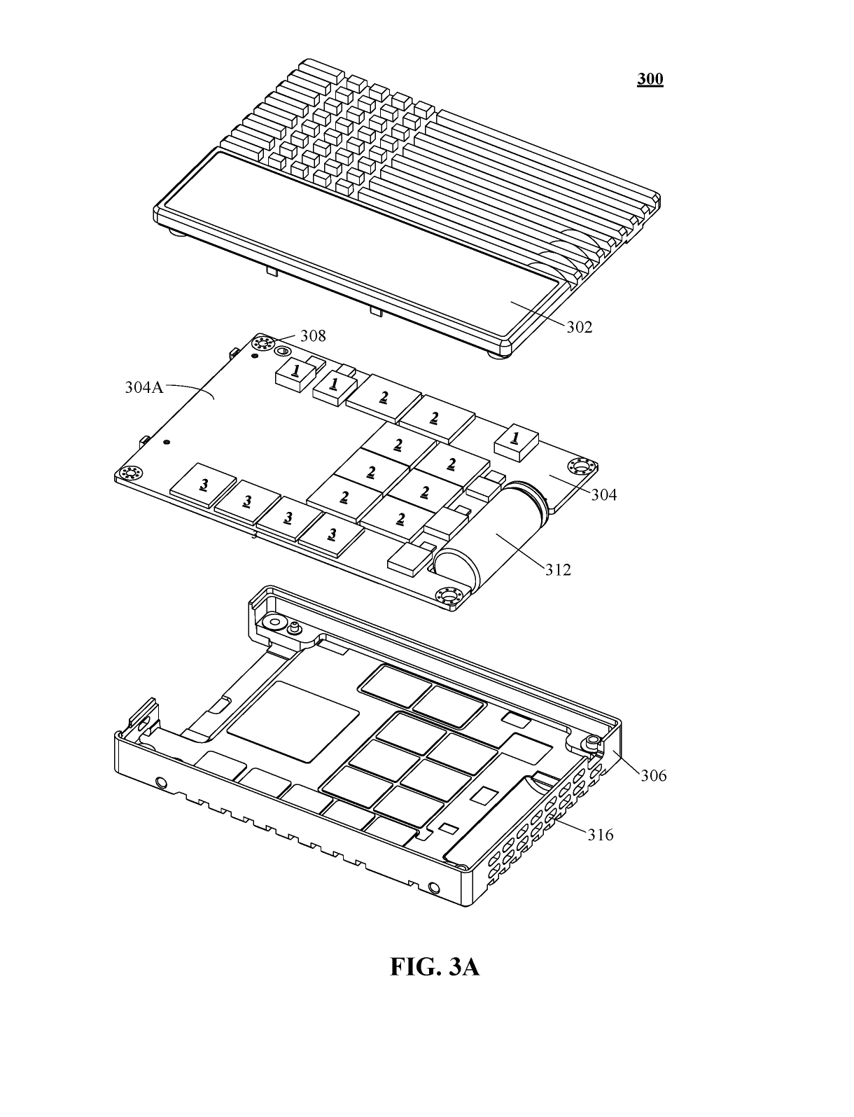

In one example as shown in FIG. 2A, the memory controller 106 and the single memory device 104 may be integrated into the memory card 202. The memory card 202 may include a PC card (Personal Computer Memory Card), a CF card, a Smart Media (SM) card, a memory stick, a multimedia card (MMC (Multi-Media Card), RS- MMC (Reduced-Size MMC), MMCmicro), an SD card (SD, miniSD, microSD, SDHC (Reduced-Size MMC)), UFS, etc. Memory card 202 may also include a memory card connector 204 that couples memory card 202 with a host (e.g., host 108 in FIG. 1).

In another example as shown in FIG. 2B, the memory controller 106 and plurality of memory devices 104 may be integrated into SSD 206. SSD 206 may also include an SSD connector 208 that couples SSD 206 with a host (e.g., host 108 in FIG. 1). In some examples, the memory capacity and/or operating speed of SSD 206 is greater than that of memory card 202.

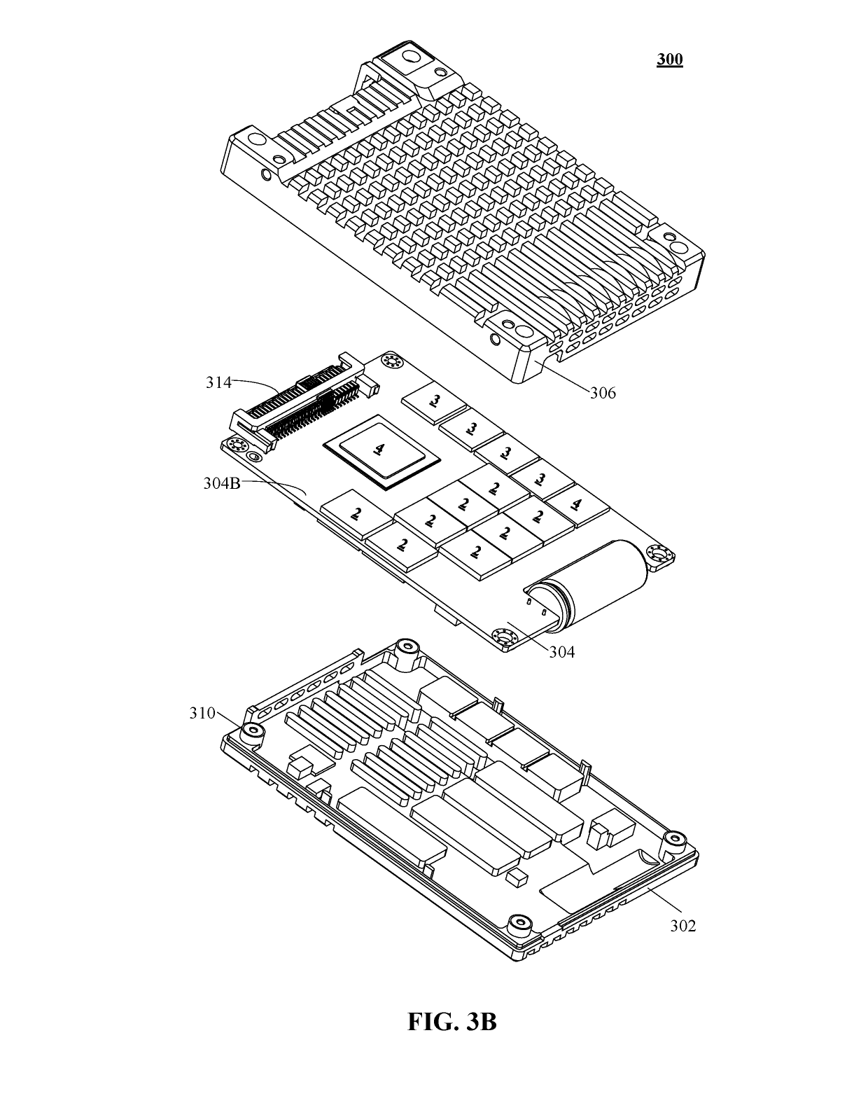

FIG. 3A and FIG. 3B are schematic diagrams of a storage device according to an example of the present disclosure. The storage device includes, but are not limited to the SSD. For ease of understanding, the SSD is taken as an example of the storage device in the following description.

Referring to FIGS. 3A and 3B, the storage device 300 may comprise a first housing 302, a substrate 304, and a second housing 306.

The substrate 304 serves as a physical substrate for fixing and connecting various components. In particular, the substrate 304 may provide mechanical support, such as carrying memory controllers, memory devices, and other components. In addition, the substrate 304 may also achieve electrical connection between various components through internal routing. As an example, referring to FIG. 3A and FIG. 3B, the substrate 304 has a first surface 304A facing the first housing 302 and a second surface 304B facing the second housing 306, components are integrated on both the first surface 304A and the second surface 304B, and the components may be electrically connected through internal routing provided on the first surface 304A and/or on the second surface 304B and/or between the first surface 304A and the second surface 304B. The substrate 304 is normally made of a semiconductor material (for example, silicon) or a printed circuit board (PCB).

The first housing 302 and the second housing 306 may be jointed with each other to form a housing. The substrate 304 may be mounted in the housing, and the housing may protect various components integrated on the substrate 304. As an example, referring to FIGS. 3A and 3B, screws 310 are arranged at four corners of the first housing 302, screw holes 308 are arranged at four corners of the substrate 304, and each screw 310 extends through a corresponding screw hole 308, so that the first housing 302 and the second housing 306 are jointed with each other to form a housing, and the substrate 304 can be connected to the housing through the screws 310. In this example, the first housing 302 and the second housing 306 may be detachably connected through the screws 310 and the screw holes 308, and the numbers of the screws 310 and the screw holes 308 are not limited to those shown in FIG. 3A and FIG. 3B, and may also be other numbers. In another example, the first housing 302 and the second housing 306 may also be jointed by using at least one of a plurality of technologies such as fastener, lock catch, and magnetic attraction.

In some examples, the storage device 300 may further comprise a memory controller and a memory device, both of which are located on the substrate 304, and the memory device is connected to the memory controller. The memory device includes a 3D NAND memory. As an example, FIG. 3A shows that a plurality of NAND chips 2 are integrated on the first surface 304A of the substrate 304. FIG. 3B shows that a main control chip 4 and a plurality of NAND chips 2 are integrated on the second surface 304B of the substrate 304. The main control chip 4 may constitute part or all of the memory controller, and the NAND chip 2 may serve as a memory device. In other examples, the number and arrangement of the NAND chip 2 and the main control chip 4 are not limited to those shown in FIG. 3A and FIG. 3B. Regarding to the memory controller and the memory device, reference may be made to related descriptions of the memory controller 106 and the memory device 104 shown in FIG. 1, FIG. 2A and FIG. 2B, respectively.

In some examples, the storage device 300 may further comprise a DRAM chip 3 on the substrate 304. The DRAM chip 3 may serve as a cache of the storage device 300 and is configured to temporarily store various configuration tables (for example, a mapping table recording a relationship of logical address to physical address mapping), data to be written into the NAND chip 2, data read from the NAND chip 2, or the like, thereby reducing the read/write delay. In another example, the storage device 300 may also adopt a design that omits the DRAM chip (DRAM-less) or uses an external DRAM chip.

In some examples, the storage device 300 may further comprise a power management integrated circuit (PMIC) located on the substrate 304. An input terminal of the power management chip 1 may be connected to a power pin, and an output terminal of the power management chip 1 may be connected to each chip. The power management chip 1 may convert an external input voltage received by the power pin into an operation voltage required by a functional unit, and supply power to each chip. As an example, FIG. 3A shows that a plurality of power management chips 1 are integrated on the first surface 304A of the substrate 304. The power management chips 1 may supply power to the main control chip 4, the NAND chip 2, the DRAM chip 3, and the like integrated on the substrate 304. In other examples, the number and arrangement of the power management chip 1 are not limited to those shown in FIG. 3A.

In some examples, the storage device 300 may further comprise a capacitor 312. The capacitor 312 serves to store electrical energy, and the capacitor 312 may provide temporary power when the storage device 300 is suddenly powered off, thereby ensuring data reliability and security. It should be noted that the enterprise SSD has higher requirements for reliability and power-off protection and generally adopts a backup power supply solution that integrates the power management chip 1 and the capacitor 312. As an example, FIG. 3A shows that the substrate 304 has an opening through the first surface 304A and the second surface 304B, and the capacitor 312 may be integrated in the opening.

In some examples, the storage device 300 may further comprise a connector 314, and the connector 314 is located on the substrate 304. The connector comprises an SATA interface, a PCIe interface, a NVMe interface, an SAS interface, or the like. As an example, FIG. 3B shows that the second surface 304B of the substrate 304 is integrated with a connector 314, there is an opening provided on a side wall of the housing, and the opening exposes the connector 314. Regarding to the connector 314, reference may be made to related descriptions of the memory card connector 204 or the SSD connector 208 shown in FIG. 2A and FIG. 2B.

In some examples, there may be further a plurality of heat dissipation holes 316 provided on the housing, and the heat dissipation holes 316 are configured to dissipate heat. As an example, FIG. 3A shows that there are a plurality of heat dissipation holes 316 provided on the side wall of the second housing 306. In other examples, the number and arrangement of the heat dissipation holes 316 are not limited to those shown in FIG. 3A.

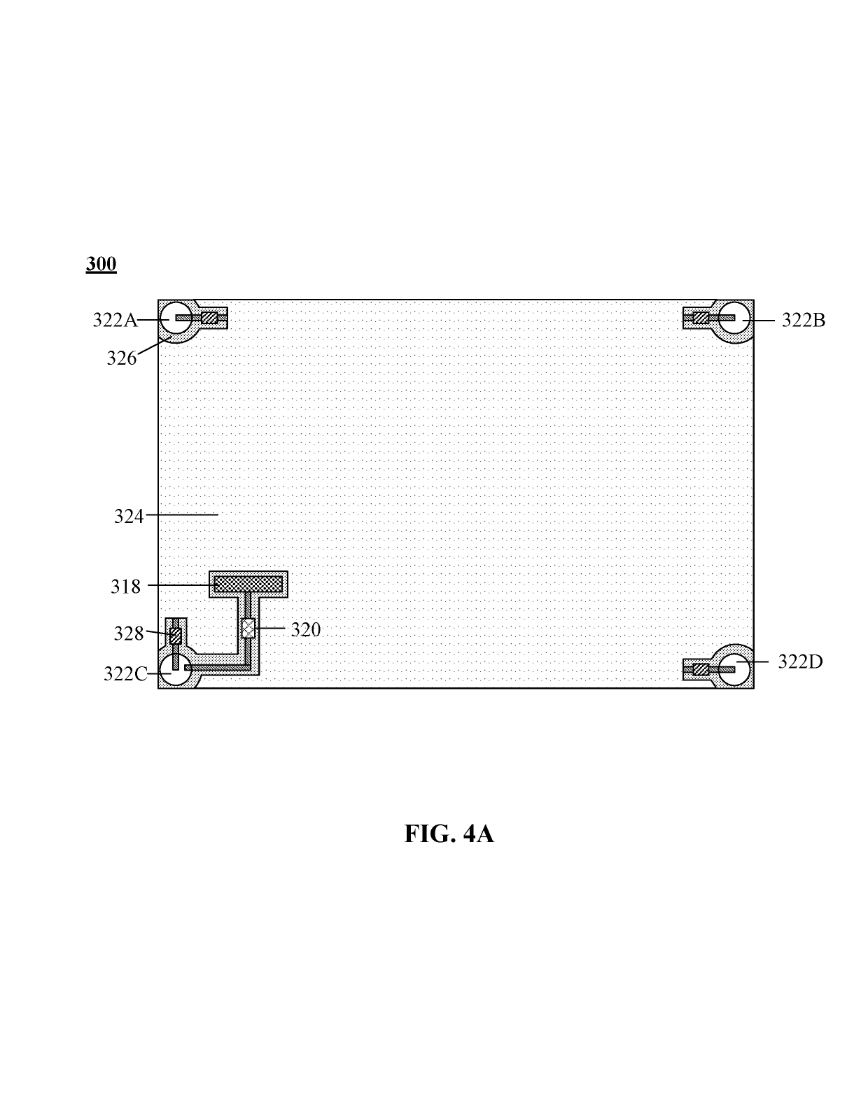

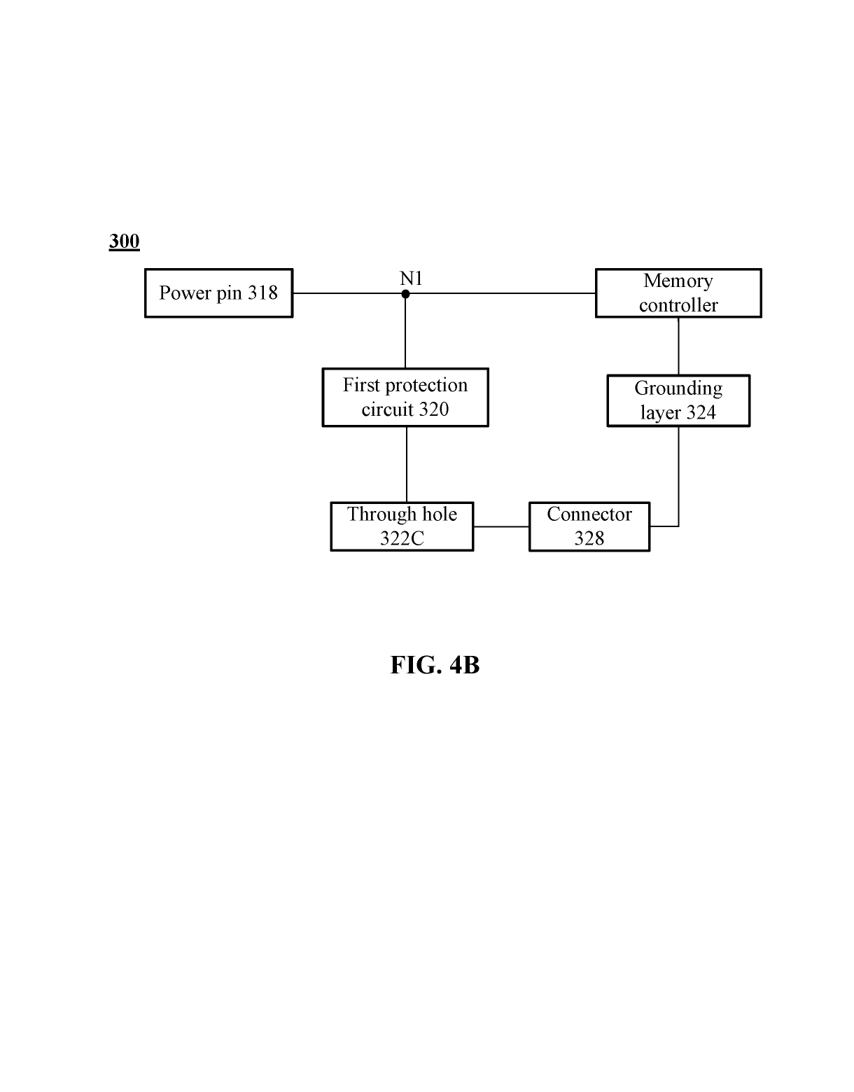

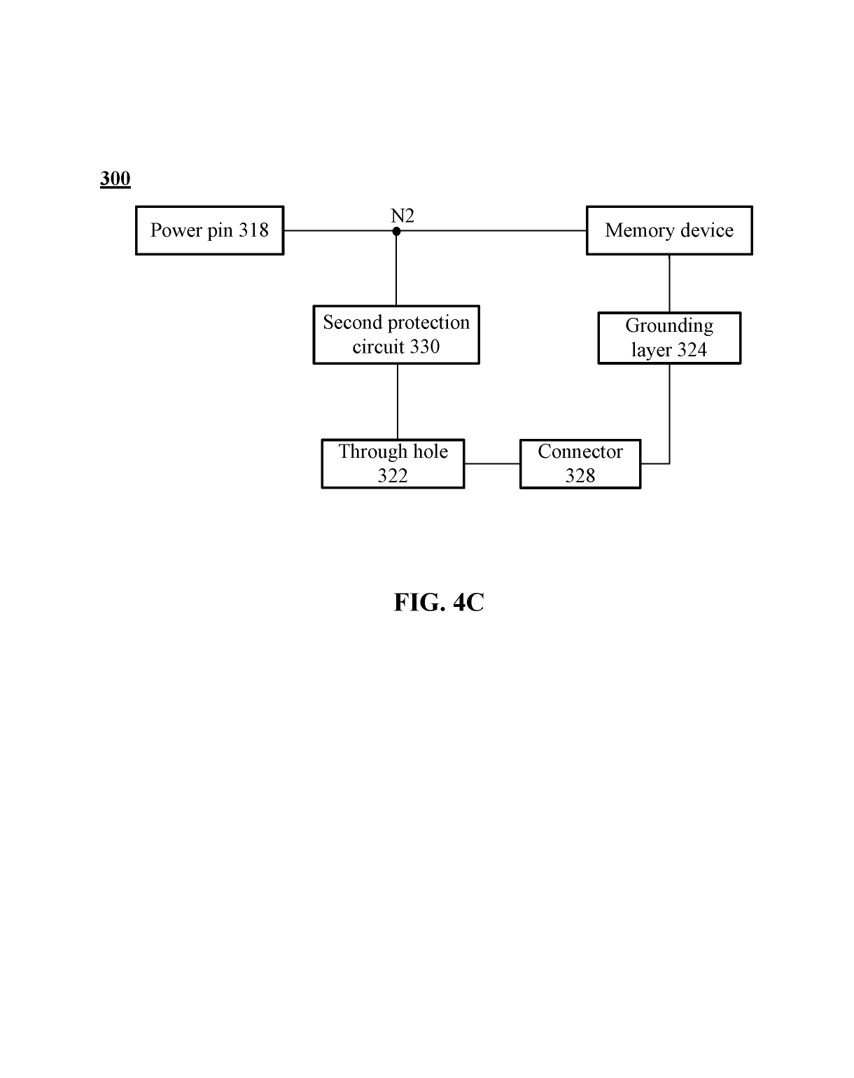

FIG. 4A is a schematic top view of a storage device having a first protection circuit provided by an example of the present disclosure, FIG. 4B is a schematic connection diagram of a storage device having a first protection circuit provided by an example of the present disclosure, and FIG. 4C is a schematic connection diagram of a storage device having a second protection circuit provided by an example of the present disclosure. In the examples of the present disclosure, the storage device comprises an SSD, for example, an enterprise SSD. The storage device provided by the examples of the present disclosure will be described below with reference to FIGS. 4A to 4C.

Referring to FIG. 3A, FIG. 3B and FIG. 4A, a power pin 318 is provided on the substrate 304 and may be connected to an external power line to provide power input for the storage device 300. In an example, the connector 314 is an SATA interface, and the SATA interface is generally divided into two segments: the short interface serves as a data interface for transmitting data, and the long interface serves as a power interface for receiving external power. It is understood that the power pins 318 may form a part of the connector 314.

Referring to FIG. 4A, a plurality of through holes, e.g., through holes 322A to 322D, are provided in the substrate 304. As an example, referring to FIG. 3A, FIG. 3B and FIG. 4A, the plurality of through holes may be screw holes 308 located at four corners of the substrate 304, and the screws 310 disposed in the screw holes 308 are used to fix the substrate 304. For example, in a case that the first housing 302 and the second housing 306 are jointed, each screw 310 extends through the corresponding screw hole 308, thereby fixing the substrate 304. It is noted that, the through holes are not limited to the screw holes 308 and may also be other through holes extending the first surface 304A and the second surface 304B of the substrate 304. The type of the through hole is not specifically limited in the examples of the present disclosure, and for ease of understanding, the following description is illustrated based on an example in which the through hole is the screw hole 308.

Referring to FIG. 3A, FIG. 3B, FIG. 4A and FIG. 4B, the storage device 300 further comprises a first protection circuit 320 and a first node N1 located on the substrate 304. The memory controller is connected to the power pin 318 through the first node N1. A first terminal of the first protection circuit 320 is connected to the first node N1, a second terminal of the first protection circuit 320 is connected to at least one of the plurality of through holes, and the through holes connected to the first protection circuit 320 are configured to be grounded.

As an example, the memory controller may be connected to the power pin 318 through routings on the substrate 304. The first node N1 may be any node on the connection line between the memory controller and the power pin 318. The first terminal of the first protection circuit 320 is connected to the first node N1, the second terminal of the first protection circuit 320 is connected to at least one screw hole 308, and the screw hole 308 connected to the first protection circuit 320 may be connected to an external ground line, that is, the through holes connected to the first protection circuit 320 are configured to be grounded. As such, in the first aspect, the transient overvoltage may be discharged to the external ground line through the first protection circuit and the screw hole connected to the first protection circuit, so as to reduce impact of the transient overvoltage on the storage device, and avoid a failure of the storage device; in the second aspect, the transient overvoltage is discharged through the screw hole, which may avoid interference with a signal line (for example, a clock signal line, a reset signal line, or a data signal line) on the substrate. It should be noted that there may be one or more through holes connected to the second terminal of the first protection circuit 320, which is not specifically limited in the present disclosure.

In some examples, the screw hole 308 connected to the first protection circuit 320 may be connected to an external ground line through a screw 310 disposed in the screw hole 308. The material of the screw 310 and the screw hole 308 may include a conductive material, such as at least one of stainless steel, carbon steel, galvanized carbon steel, nickel-plated carbon steel, copper, and aluminum. In other examples, the screw hole 308 connected to the first protection circuit 320 may be directly connected to an external ground line.

In some examples, referring to FIGS. 3A, 3B and 4A, the substrate 304 further comprises a grounding layer 324 and an isolation layer 326. A grounding terminal of the memory controller and a grounding terminal of the memory device are both connected to the grounding layer 324, and the isolation layer 326 is located between the through holes and the grounding layer 324.

As an example, the grounding layer 324 may be located between the first surface 304A and the second surface 304B of the substrate 304. The grounding terminals of the main control chip, the NAND chip, the DRAM chip, and the like integrated on the substrate 304 may be connected to the grounding layer 324 through internal routing, so as to provide a ground level VSS for the grounding terminals of the chips on the substrate when the storage device 300 is operating.

Typically, the transient overvoltage discharge is through a path of the grounding layer 324. To be specific, the transient overvoltage protection device is connected in parallel between the power pin 318 and the grounding layer 324. The transient overvoltage generated by the power supply is discharged to the grounding layer 324 through the protection device, which may cause large fluctuation and interference of the potential on the grounding layer 324, and the fluctuation and interference of the potential on the grounding layer 324 may cause increased interference of the signal line on the substrate 304.

In the examples of the present disclosure, the grounding terminals of the memory controller and the memory device are both connected to the grounding layer 324. The second terminal of the first protection circuit 320 is connected to a grounded through hole, that is, each chip on the substrate and the first protection circuit 320 are connected to different grounding terminals respectively, and the through hole and the grounding layer 324 are physically isolated by the isolation layer 326, which may reduce the fluctuation and interference of the potential on the grounding layer 324, thereby reducing the interference of the signal lines on the substrate 304. A material of the isolation layer 326 includes an insulating material, for example, silicon oxide, silicon nitride, or silicon oxynitride.

In some examples, the second terminal of the first protection circuit 320 is connected to one of the plurality of through holes that is closest to the first protection circuit 320.

As an example, referring to FIG. 4A, the second terminal of the first protection circuit 320 is connected to the through hole 322C, so that the discharge path of the transient overvoltage may be shortened, and the transient overvoltage can be discharged quickly.

In some examples, the storage device 300 further comprises a connector 328 located on the substrate 304. A first terminal of the connector 328 is connected to the through holes connected to the first protection circuit 320, and a second terminal of the connector 328 is connected to the grounding layer 324.

As an example, referring to FIGS. 4A and 4B, a first terminal of the connector 328 is connected to the through hole 322C, and a second terminal of the connector 328 is connected to the grounding layer 324. As such, the through hole 322C and the grounding layer 324 may be bridged by the connector 328 on the surface of the substrate 304, which may replace the bridging routings on the surface of the substrate 304, optimize the grounding path, suppress electromagnetic interference, and ensure the stability of the electrical connection.

In some examples, the connector 328 comprises at least one of a 0Ω resistor, a capacitor, an inductor, and a magnetic bead. As an example, FIG. 4A shows that each screw hole 308 and the grounding layer 324 are connected through a 0Ω resistor, and the 0Ω resistor may serve as an alternative solution of the bridging routings, to avoid an antenna effect of high-frequency signal due to the bridging routings, and simplify substrate routing. Because the 0Ω resistor adopts a better patch packaging form than the through hole, the parasitic inductance is smaller, without affecting the plane integrity of the grounding layer.

In some examples, referring to FIG. 3A, FIG. 3B and FIG. 4C, the storage device 300 further comprises a second protection circuit 330 and a second node N2 located on the substrate 304. The memory device is connected to the power pin 318 through the second node N2. A first terminal of the second protection circuit 330 is connected to the second node N2, a second terminal of the second protection circuit 330 is connected to at least one of the plurality of through holes, and the through holes connected to the second protection circuit 330 are configured to be grounded.

As an example, the NAND chip may be connected to the power pin 318 through routings on the substrate 304. The second node N2 may be any node on the connection line between the NAND chip and the power pin 318. The first terminal of the second protection circuit 330 is connected to the second node N2, the second terminal of the second protection circuit 330 is connected to at least one screw hole 308, and the screw hole 308 connected to the second protection circuit 330 may be connected to an external ground line, that is, the through holes connected to the second protection circuit 330 are configured to be grounded. As such, the transient overvoltage can also be discharged to the external ground line through the second protection circuit 330 and the screw hole 308 connected to the second protection circuit 330, thereby reducing the impact of the transient overvoltage on the storage device and avoiding the failure of the storage device. It should be noted that there may be one or more screw holes 308 connected to the second terminal of the second protection circuit 330, which is not specifically limited in the present disclosure. In addition, the through holes connected to the second protection circuit 330 and the grounding layer 324 may also be bridged by another connector 328 on the surface of the substrate 304.

In some examples, a screw hole connected to the second protection circuit 330 may be connected to an external ground line by a screw disposed in the screw hole. Regarding to materials of the screw and the screw hole, reference may be made to related foregoing descriptions of the screw 310 and the screw hole 308. In other examples, the screw hole connected to the second protection circuit 330 may be directly connected to the external ground line.

In some examples, the second terminal of the second protection circuit 330 is connected to one of the plurality of through holes that is closest to the second protection circuit 330. As such, a discharge path of the transient overvoltage may be shortened, so that the transient overvoltage can be discharged quickly. In practical applications, the screw hole connected to the second terminal of the first protection circuit 320 and the screw hole connected to the second terminal of the second protection circuit 330 may be properly selected according to the locations of the memory controller and the memory device on the substrate 304. The second terminal of the first protection circuit 320 and the second terminal of the second protection circuit 330 may be connected to the same screw hole or different screw holes.

In some examples, the storage device 300 further comprises a power management circuit on the substrate 304. An input terminal of the power management circuit is connected to the power pin 318 through the first node N1, and an output terminal of the power management circuit is connected to the memory controller. As an example, the power management circuit may comprise the power management chip 1 shown in FIG. 3A. As another example, the power management circuit may comprise both the power management chip 1 and the capacitor 312 shown in FIG. 3A, that is, the power management chip 1 and the capacitor 312 together constitute the power management circuit. Regarding to the power management chip 1 and the capacitor 312, reference may be made to the foregoing related descriptions.

In some examples, a ratio of a sum of areas of the plurality of through holes to an area of the substrate 304 is less than 0.05. As an example, the sum of the areas of the four through holes 322A to 322D shown in FIG. 4A is S1, and the area of the substrate 304 is S2, 0<S1/S2<0.05, that is, the plurality of through holes occupy a small planar area on the substrate 304, and thus occupy a small space of the substrate 304, which is beneficial to ensure the space for routings on the substrate 304 and meet the requirements of high-density routings on the substrate 304.

In some examples, the first protection circuit 320 is configured to discharge the transient overvoltage received by the power pin 318, such that the voltage received by the memory controller is less than or equal to the operation voltage of the memory controller. In an example of the present disclosure, the first protection circuit 320 may discharge the transient overvoltage received by the power pin 318 to clamp the transient overvoltage at the first node to a safe level, so that the voltage received by the memory controller is less than or equal to the operation voltage of the memory controller, thereby protecting the memory controller.

In some examples, the second protection circuit 330 is configured to discharge the transient overvoltage received by the power pin 318, such that the voltage received by the memory device is less than or equal to the operation voltage of the memory device. In an example of the present disclosure, the second protection circuit 330 may discharge the transient overvoltage received by the power pin 318 to clamp the transient overvoltage at the second node to a safe level, so that the voltage received by the memory device is less than or equal to the operation voltage of the memory device, thereby protecting the memory device.

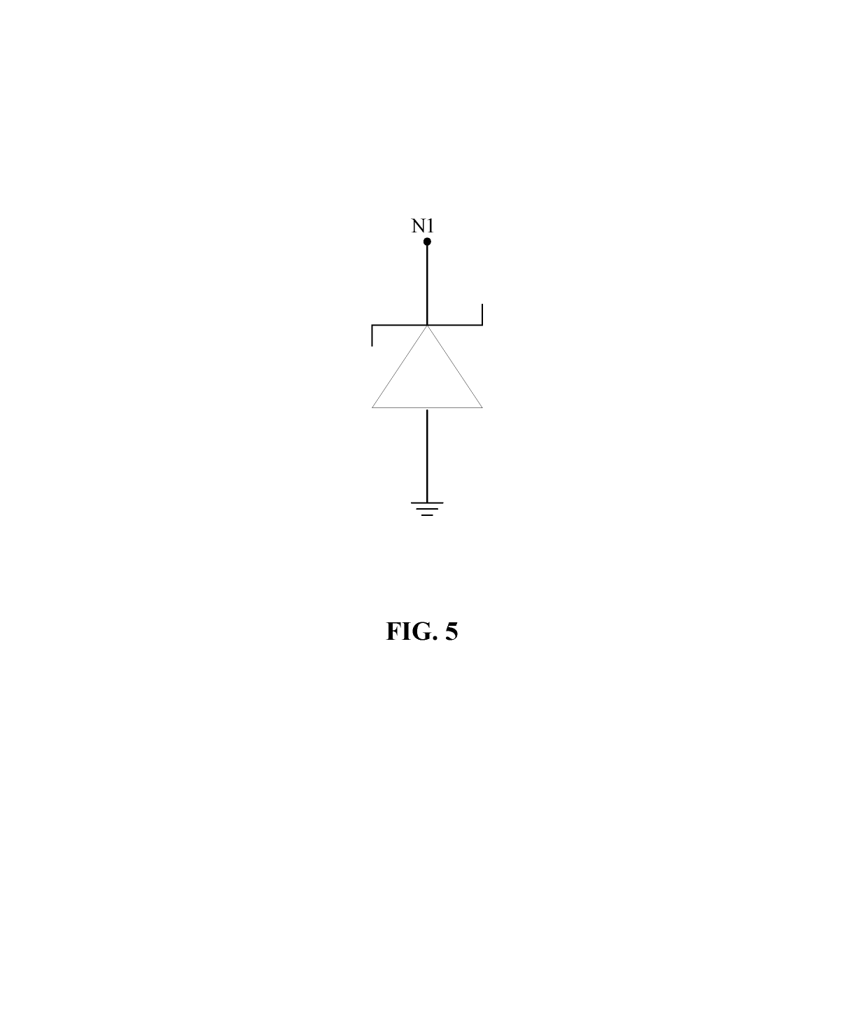

In some examples, the first protection circuit 320 and the second protection circuit 330 each comprise a transient voltage suppressor (TVS). The first protection circuit 320 and the second protection circuit 330 may also be other electronic components, for example, piezo-resistors, multi-layer piezo-resistors, capacitors, and the like. FIG. 5 is a schematic diagram of a transient voltage suppressor provided by an example of the present disclosure, and a discharge of a transient voltage will be described below with reference to FIG. 5.

Referring to FIG. 4A and FIG. 5, the transient voltage suppressor may be connected in parallel into the circuit, for example, the first terminal of the transient voltage suppressor is connected to the first node N1. When the storage device 300 operates normally, the transient voltage suppressor is in a high resistance state (i.e., an off state), and has no influence on the storage device 300; When the voltage received by the power pin 318 exceeds the breakdown voltage of the transient voltage suppressor (i.e., the transient overvoltage is received), the transient voltage suppressor responds rapidly (the response time may reach a picosecond level), and changes from the high resistance state to a low resistance state to form a low impedance path, which clamps the transient overvoltage to a safe level and absorbs the transient energy, and after the transient overvoltage disappears, the transient voltage suppressor automatically returns to the high resistance state. It can be understood that the transient overvoltage received by the power pin 318 may be conducted to the grounded screw hole through the transient voltage suppressor, then conducted to the housing, and finally conducted to the external ground line, so as to discharge the transient overvoltage.

It should be noted that a voltage for normal operation of the SSD is generally a dozen of volts (for example, 12 V). If a transient high voltage of tens of volts or even hundreds of volts occurs during the operation of the SSD, the transient high voltage may be discharged by the transient voltage suppressor, so that the voltage received by the memory controller and/or the memory device is reduced to a dozen of volts, thereby preventing the transient high voltage from damaging the memory controller and/or the memory device.

Based on a concept similar to the above storage device, an example of the present disclosure further provides a semiconductor device.

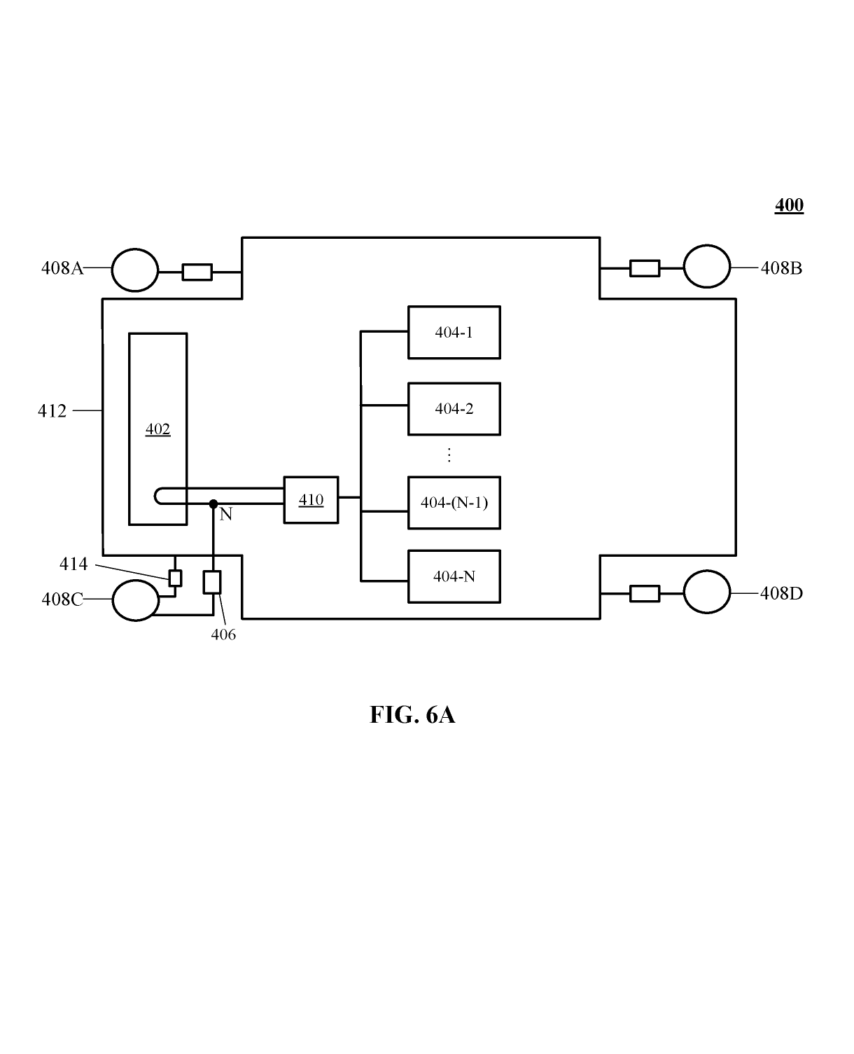

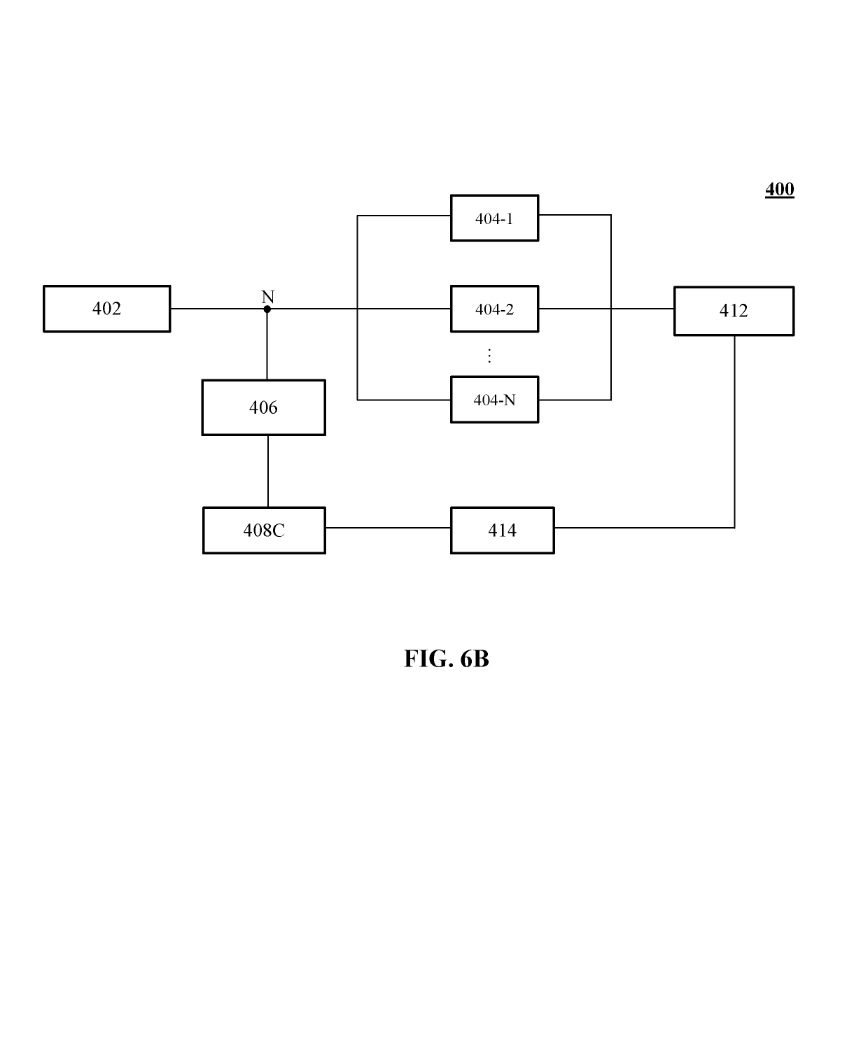

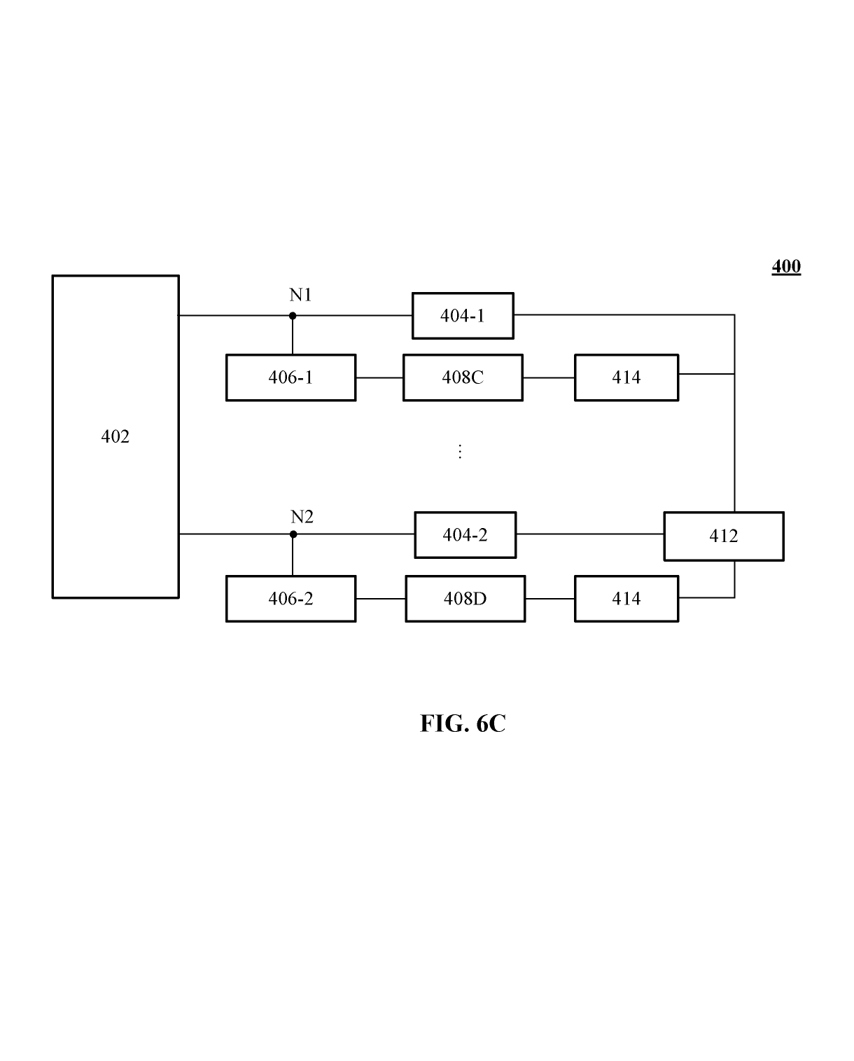

FIG. 6A is a schematic diagram of a semiconductor device having a protection circuit provided by an example of the present disclosure. FIG. 6B is a schematic connection diagram of a semiconductor device having a protection circuit provided by an example of the present disclosure. FIG. 6C is a schematic connection diagram of a semiconductor device having a first protection circuit and a second protection circuit provided by an example of the present disclosure. The semiconductor device provided by an example of the present disclosure will be described below with reference to FIGS. 6A to 6C.

Referring to FIG. 6A, the semiconductor device 400 comprises a substrate, and a chip, a protection circuit 406, and a node N located on the substrate; a power pin 402 is provided on the substrate, and a plurality of through holes are provided in the substrate; the chip is connected to the power pin 402 through the node N, a first terminal of the protection circuit 406 is connected to the node N, a second terminal of the protection circuit 406 is connected to at least one of the plurality of through holes, and the through holes connected to the protection circuit 406 are configured to be grounded.

As an example, FIG. 6A shows four through holes 408A to 408D, and four through holes 408A to 408D may be screw holes arranged at four corners of the substrate. Regarding to the screw holes, reference may be made to the related description of the screw hole 308. It is noted that, the through hole is not limited to the screw hole and may also be other through holes extending through the first surface and the second surface of the substrate. The examples of the present disclosure do not specifically limit the type of the through hole, and for ease of understanding, the following description is illustrated based on an example in which the through hole is the screw hole.

As an example, the chip may be connected to the power pin 402 through routings on the substrate. The node N may be any node on the connection line between the chip and the power pin 402. The first terminal of the protection circuit 406 is connected to the node N, the second terminal of the protection circuit 406 is connected to at least one screw hole, and the screw hole connected to the protection circuit 406 may be connected to an external ground line, that is, the through holes connected to the protection circuit 406 are configured to be grounded. As such, in the first aspect, the transient overvoltage may be discharged to the external ground line through the protection circuit 406 and the screw hole connected to the protection circuit 406, thereby reducing the impact of the transient overvoltage on the semiconductor device 400 and avoiding the failure of the semiconductor device 400; in the second aspect, the transient overvoltage is discharged through the screw hole, thereby avoiding the interference to the signal line on the substrate. It should be noted that there may be one or more through holes connected to the second terminal of the protection circuit 406, which is not specifically limited in the present disclosure.

In some examples, the chip comprises at least one of a memory device and a memory controller, and regarding to the memory controller and the memory device, reference may be made to related descriptions of the memory controller 106 and the memory device 104 shown in FIG. 1, FIG. 2A, and FIG. 2B, respectively. The chip may also be another type of chip, for example, a computing chip, a sensor chip, a communication chip, a radio frequency chip, a network chip, an analog chip, a logic chip, or a system-level chip.

In some examples, referring to FIG. 6A to FIG. 6C, the substrate further comprises a grounding layer 412 and an isolation layer, the grounding terminal of the chip is connected to the grounding layer 412, and the isolation layer is located between the through holes and the grounding layer 412.

As an example, the grounding layer 412 may be located between the first surface and the second surface of the substrate, and the grounding terminal of the chip integrated on the substrate may be connected to the grounding layer 412 through internal routing, so as to provide the ground level VSS for the grounding terminal of the chip on the substrate when the semiconductor device 400 operates.

In an example of the present disclosure, the grounding terminal of the chip is connected to the grounding layer 412. The second terminal of the protection circuit 406 is connected to the grounded through hole, that is, the chip on the substrate and the protection circuit 406 are connected to different grounding terminals respectively, and the through hole and the grounding layer 412 are physically isolated by the isolation layer, which can reduce the fluctuation and interference of the potential on the grounding layer 412, thereby reducing the interference of the signal lines on the substrate. A material of the isolation layer includes an insulating material, for example, silicon oxide, silicon nitride, or silicon oxynitride. For ease of understanding, the isolation layer is omitted in FIG. 6A.

In some examples, the second terminal of the protection circuit 406 is connected to one of the plurality of through holes that is closest to the protection circuit 406. As an example, referring to FIG. 6A, the second terminal of the protection circuit 406 is connected to the through hole 408C, so that the discharge path of the transient overvoltage can be shortened, and the transient overvoltage can be discharged quickly.

In some examples, the semiconductor device 400 further comprises a connector 414 on the substrate, a first terminal of the connector 414 is connected to the through holes connected to the protection circuit 406, and a second terminal of the connector 414 is connected to the grounding layer 412.

As an example, referring to FIGS. 6A and 6B, a first terminal of the connector 414 is connected to the through hole 408C, and a second terminal of the connector 414 is connected to the grounding layer 412. As such, the through hole 408C and the grounding layer 412 can be bridged by the connector 414 on the substrate surface, which can replace the bridging routings on the substrate surface, optimize the grounding path, suppress electromagnetic interference, and ensure the stability of the electrical connection.

In some examples, the connector 414 comprises at least one of a 0Ω resistor, a capacitor, an inductor, and a magnetic bead.

In some examples, the semiconductor device 400 comprises a plurality of chips each connected to a power pin 402 through a node N. As an example, FIGS. 6A and 6B show a plurality of chips 404-1 to 404-N connected to a power pin 402 through a node N. In an example of the present disclosure, the plurality of chips are connected to the power pin 402 through the same node N, and the protection circuit 406 may be connected in parallel at the node N, so as to achieve protection for the plurality of chips.

In some examples, referring to FIG. 6A and FIG. 6C, the semiconductor device 400 comprises a plurality of chips and a plurality of protection circuits. A first chip 404-1 of the plurality of chips is connected to the power pin 402 through a first node N1, a second chip 404-2 of the plurality of chips is connected to the power pin 402 through a second node N2 different from the first node N1. A first terminal of a first protection circuit 406-1 of the plurality of protection circuits is connected to the first node N1, a first terminal of a second protection circuit 406-2 of the plurality of protection circuits is connected to the second node N2, and a second terminal of the first protection circuit 406-1 and a second terminal of the second protection circuit 406-2 are connected to a same one or different ones of the through holes.

As an example, FIG. 6C shows a first chip 404-1 connected to the power pin 402 through a first node N1 and a second chip 404-2 connected to the power pin 402 through a second node N2. A first terminal of the first protection circuit 406-1 is connected to the first node N1, and a second terminal of the first protection circuit 406-1 is connected to the through hole 408C. A first terminal of the second protection circuit 406-2 is connected to the second node N2, and a second terminal of the second protection circuit 406-2 is connected to the through hole 408D. The through hole 408C and the through hole 408D both may be connected to the grounding layer 412 through corresponding connectors 414. In FIG. 6C, the second terminal of the first protection circuit 406-1 and the second terminal of the second protection circuit 406-2 are connected to different through holes. In other examples, the second terminal of the first protection circuit 406-1 and the second terminal of the second protection circuit 406-2 in FIG. 6C may be connected to the same through hole.

It should be noted that, in the examples of the present disclosure, the chip connected to the power pin 402 through the first node N1 may be referred to as a first chip, the chip connected to the power pin 402 through the second node N2 may be referred to as a second chip, and the number of the first chip and the second chip may be one or more, which is not specifically limited in the examples of the present disclosure.

In the examples of the present disclosure, the first chip is connected to the power pin 402 through the first node N1, and the second chip is connected to the power pin 402 through the second node N2 different from the first node N1, so that the first protection circuit and the second protection circuit may be connected in parallel at the first node N1 and the second node N2, respectively, so as to achieve protection for a plurality of chips.

In some examples, the protection circuit 406 comprises a transient voltage suppressor. Regarding to the transient voltage suppressor, reference may be made to the related description of FIG. 5.

In some examples, the protection circuit 406 is configured to discharge the transient overvoltage received by the power pin 402, such that the voltage received by the chip is less than or equal to the operation voltage of the chip. In an example of the present disclosure, the protection circuit 406 may discharge the transient overvoltage received by the power pin 402 to clamp the transient overvoltage at the node N to a safe level, so that the voltage received by the chip is less than or equal to the operation voltage of the chip, thereby protecting the chip.

In some examples, a ratio of a sum of areas of the plurality of through holes to an area of the substrate is less than 0.05.

In some examples, the semiconductor device 400 further comprises a power management circuit 410 located on the substrate. An input terminal of the power management circuit 410 is connected to the power pin 402 through the node N. An output terminal of the power management circuit 410 is connected to the chip. Regarding to the power management circuit 410, reference may be made to the related description of the foregoing power management chip 1.

In some examples, the plurality of through holes comprises screw holes arranged at four corners of the substrate; the semiconductor device 400 further comprises a housing and screws, the substrate is mounted in the housing, the screws extend through the screw holes, and the substrate is connected to the housing through the screws. Regarding to the substrate, the screw hole, and the screw, reference may be made to related descriptions of the substrate 304, the screw hole 308, and the screw 310 in FIG. 3A and FIG. 3B.

Based on a concept similar to that of the above storage device, an example of the present disclosure further provides an electronic apparatus. The electronic apparatus comprises: a storage device according to any one of the above examples or a semiconductor device according to any one of the above examples; and a host coupled to the storage device or the semiconductor device.

In the examples of the present disclosure, the electronic apparatus may comprise the storage device or the semiconductor device in any of the foregoing examples, and the electronic apparatus may also achieve the technical effects that may be achieved by the storage device or the semiconductor device in the foregoing examples, which will not be repeated here. For the electronic apparatus, reference may be made to the related description of the electronic apparatus 100 shown in FIG. 1, which will not be illustrated in detail here.

The features disclosed in several device examples provided by the present disclosure may be arbitrarily combined without conflict to obtain new device examples.

It should be understood that “one example” or “an example” throughout the specification means that particular features, structures, or characteristics related to the example are included in at least one example of the present disclosure. Therefore, “in one example” or “in an example” throughout the specification does not necessarily refer to the same example. Furthermore, the particular features, structures, or characteristics may be combined in any suitable manner in one or more examples. It should be understood that, in various examples of the present disclosure, the sequence numbers of the above processes do not indicate an execution sequence, and the execution sequence of each process should be determined by its function and internal logic, and should not constitute any limitation on the implementation process of the examples of the present disclosure. The sequence numbers of the above examples of the present disclosure are only for description, and do not represent the advantages or disadvantages of the examples.

It should be noted that, the terms “including”, “comprising”, or any other variation thereof herein are intended to encompass a non-exclusive inclusion, so that a process, a method, an article, or an apparatus that includes a series of elements includes not only those elements, but also other elements that are not explicitly listed, or elements inherent to such a process, method, article, or apparatus. Without more constraints, an element defined by the phrase “comprising one” does not preclude the existence of additional identical elements in the process, method, article, or apparatus that comprises the element.

The above descriptions are only some implementations of the present disclosure, and the scope of protection of the present disclosure is not limited thereto. Any variant or replacement that may be readily conceived by those skilled in the art within the scope of the present disclosure should be encompassed within the scope of protection of the present disclosure.

What is claimed is:

1. A storage device, comprising:
a substrate, wherein a power pin is provided on the substrate, and a plurality of through holes are provided in the substrate; and
a memory controller, a memory device, a first protection circuit and a first node on the substrate, wherein the memory controller is connected to the power pin through the first node, the memory device is connected to the memory controller, a first terminal of the first protection circuit is connected to the first node, and a second terminal of the first protection circuit is connected to at least one of the plurality of through holes, and wherein through holes connected to the first protection circuit are configured to be grounded.

2. The storage device according to claim 1, wherein the substrate further comprises a grounding layer and an isolation layer, and wherein a grounding terminal of the memory controller and a grounding terminal of the memory device are connected to the grounding layer, and the isolation layer is located between the plurality of through holes and the grounding layer.

3. The storage device according to claim 2, further comprising a connector on the substrate, wherein a first terminal of the connector is connected to the through holes connected to the first protection circuit, and a second terminal of the connector is connected to the grounding layer.

4. The storage device according to claim 3, wherein the connector comprises at least one of a 0Ω resistor, a capacitor, an inductor, and a magnetic bead.

5. The storage device according to claim 1, further comprising:
a second protection circuit and a second node on the substrate, wherein the memory device is connected to the power pin through the second node, a first terminal of the second protection circuit is connected to the second node, and a second terminal of the second protection circuit is connected to at least one of the plurality of through holes, and wherein through holes connected to the second protection circuit are configured to be grounded.

6. The storage device according to claim 5, wherein a second terminal of the first protection circuit is connected to one of the plurality of through holes that is closest to the first protection circuit; and a second terminal of the second protection circuit is connected to one of the plurality of through holes that is closest to the second protection circuit.

7. The storage device according to claim 5, wherein the first protection circuit and the second protection circuit each comprise a transient voltage suppressor.

8. The storage device according to claim 5, wherein
the first protection circuit is configured to discharge a transient overvoltage received by the power pin, such that a voltage received by the memory controller is less than or equal to an operation voltage of the memory controller; and
the second protection circuit is configured to discharge the transient overvoltage received by the power pin, such that a voltage received by the memory device is less than or equal to an operation voltage of the memory device.

9. The storage device according to claim 1, wherein a ratio of a sum of areas of the plurality of through holes to an area of the substrate is less than 0.05.

10. The storage device according to claim 1, further comprising:
a power management circuit on the substrate, wherein an input terminal of the power management circuit is connected to the power pin through the first node, and an output terminal of the power management circuit is connected to the memory controller.

11. The storage device according to claim 1, wherein the plurality of through holes comprise screw holes arranged at four corners of the substrate, and screws disposed in the screw holes are configured to fix the substrate.

12. A semiconductor device, comprising:
a substrate, wherein a power pin is provided on the substrate, and a plurality of through holes are provided in the substrate; and
a chip, a protection circuit, and a node on the substrate, wherein the chip is connected to the power pin through the node, a first terminal of the protection circuit is connected to the node, and a second terminal of the protection circuit is connected to at least one of the plurality of through holes, and wherein through holes connected to the protection circuit are configured to be grounded.

13. The semiconductor device according to claim 12, wherein the substrate further comprises a grounding layer and an isolation layer, and wherein a grounding terminal of the chip is connected to the grounding layer, and the isolation layer is located between the plurality of through holes and the grounding layer.

14. The semiconductor device according to claim 13, further comprising a connector on the substrate, wherein a first terminal of the connector is connected to the through holes connected to the protection circuit, and a second terminal of the connector is connected to the grounding layer.

15. The semiconductor device according to claim 14, wherein the connector comprises at least one of a 0Ω resistor, a capacitor, an inductor, and a magnetic bead.

16. The semiconductor device according to claim 12, wherein the chip includes a plurality of chips that are all connected to the power pin through the node.

17. The semiconductor device according to claim 12, wherein the chip includes a plurality of chips and the protection circuit includes a plurality of protection circuits, a first chip of the plurality of chips is connected to the power pin through a first node, and a second chip of the plurality of chips is connected to the power pin through a second node different from the first node, and wherein a first terminal of a first protection circuit of the plurality of protection circuits is connected to the first node, a first terminal of a second protection circuit of the plurality of protection circuits is connected to the second node, and a second terminal of the first protection circuit and a second terminal of the second protection circuit are connected to a same one or different ones of the plurality of through holes.

18. The semiconductor device according to claim 12, wherein the second terminal of the protection circuit is connected to one of the plurality of through holes that is closest to the protection circuit.

19. The semiconductor device according to claim 12, wherein the protection circuit comprises a transient voltage suppressor.

20. An electronic apparatus, comprising:
a storage device, comprising:
a substrate, wherein a power pin is provided on the substrate, and a plurality of through holes are provided in the substrate; and
a memory controller, a memory device, a first protection circuit and a first node on the substrate, wherein the memory controller is connected to the power pin through the first node, the memory device is connected to the memory controller, a first terminal of the first protection circuit is connected to the first node, and a second terminal of the first protection circuit is connected to at least one of the plurality of through holes, and wherein through holes connected to the first protection circuit are configured to be grounded.
